(19) United States
(12) Patent Application Publication
(10) Pub. No.: US 2024/0268135 A1
(43) Pub. Date: Aug. 8, 2024

(54) LIGHT EMITTING DEVICE, LIGHT EMITTING BASE PLATE AND LIGHT EMITTING APPARATUS

(71) Applicant: BOE TECHNOLOGY GROUP CO., LTD., Beijing (CN)

(72) Inventors: Qian Jin, Beijing (CN); Xiaoyun Liu, Beijing (CN); Wei Huang, Beijing (CN); Juan Zhang, Beijing (CN); Zhiqiang Jiao, Beijing (CN); Xiaohu Li, Beijing (CN)

(73) Assignee: BOE TECHNOLOGY GROUP CO., LTD., Beijing (CN)

(21) Appl. No.: 18/021,250

(22) PCT Filed: Jun. 29, 2022
(86) PCT No.: PCT/CN2022/102478

§ 371 Date: Feb. 14, 2023

(51) Int. Cl. H10K 50/115; H10K 50/818; H10K 59/35; H10K 59/38; H10K 59/80

(52) U.S. Cl. CPC H10K 50/115; H10K 50/818; H10K 59/35; H10K 59/38; H10K 59/873; H10K 59/877

(57) ABSTRACT

A light emitting device, a light emitting base plate and a light emitting apparatus, which relates to the technical field of displaying. A light emitting device includes: a first electrode; a second electrode facing the first electrode; and at least one luminescent layer provided in stack between the first electrode and the second electrode, wherein the at least one luminescent layer includes: a first luminescent material for emitting a first light ray when driven by a current or voltage; and a second luminescent material for emitting a second light ray when driven by a current or voltage; wherein a color of the first light ray and a color of the second light ray are different.

### TECHNICAL FIELD

The present disclosure relates to the technical field of displaying, and particularly relates to a light emitting device, a light emitting base plate and a light emitting apparatus.

### BACKGROUND

Organic Light Emitting Diode (OLED) is an active light emitting device, has the advantages such as self-illumination, a wide visual angle, a high reaction speed, a high luminous efficiency, a low operating voltage and a simple manufacture procedure, and thus has become the next generation of hotspot light emitting device.

### SUMMARY

The present disclosure provides a light emitting device, wherein the light emitting device comprises:
a first electrode;
a second electrode facing the first electrode; and
at least one luminescent layer provided in stack between the first electrode and the second electrode, wherein the at least one luminescent layer comprises:
   a first luminescent material for emitting a first light ray when driven by a current or voltage; and
   a second luminescent material for emitting a second light ray when driven by a current or voltage;
   wherein a color of the first light ray and a color of the second light ray are different.

In an alternative implementation, a wavelength of the first light ray is greater than or equal to 440 nanometers, and less than or equal to 490 nanometers.

In an alternative implementation, a wavelength of the second light ray is greater than or equal to 500 nanometers, and less than or equal to 650 nanometers.

In an alternative implementation, the at least one luminescent layer includes at least one first luminescent layer and at least one second luminescent layer;
the first luminescent layer comprises the first luminescent material; and
the second luminescent layer comprises the second luminescent material, or the second luminescent layer comprises the first luminescent material and the second luminescent material.

In an alternative implementation, the first electrode is a reflection-type electrode, and the second electrode is a transmission-type electrode or a semi-transmission-type electrode; and
a luminous efficiency of the first luminescent material is less than or equal to a luminous efficiency of the second luminescent material, and the first luminescent layer is located on one side of the second luminescent layer that is closer to the first electrode.

In an alternative implementation, the at least one first luminescent layer is located on one side of the at least one second luminescent layer that is closer to the first electrode.

In an alternative implementation, the first electrode is an anode, the second electrode is a cathode, and the light emitting device further comprises at least one of.
a first hole injection layer, a first hole transporting layer and a first electron blocking layer that are arranged in stack between the first electrode and the at least one luminescent layer, wherein the first hole injection layer is closer to the first electrode;
a first hole blocking layer, a first electron transporting layer, an electric-charge generating layer, a second hole injection layer, a second hole transporting layer and a second electron blocking layer that are arranged in stack between two neighboring instances of the luminescent layer, wherein the first hole blocking layer is closer to the first electrode;
a second hole blocking layer, a second electron transporting layer and an electron injection layer that are arranged in stack between the at least one luminescent layer and the second electrode, wherein the electron injection layer is closer to the second electrode; and
an optical-extraction layer provided on one side of the second electrode that is opposite to the first electrode.

In an alternative implementation, both of the first luminescent material and the second luminescent material comprise at least one of an organic electroluminescent material and a quantum dot.

In an alternative implementation, the first light ray is a blue-color light ray;
a spectral intensity of the first light ray emitted by the light emitting device is a first intensity, and a spectral intensity of the second light ray emitted by the light emitting device is a second intensity, wherein the first intensity is greater than or equal to the second intensity, and the second intensity is greater than 0; and/or
a brightness of the first light ray emitted by the light emitting device is a first brightness, and a brightness of a total light ray emitted by the light emitting device is a second brightness, wherein a ratio of the first brightness to the second brightness is greater than or equal to 14%.

The present disclosure provides a light emitting base plate, wherein the light emitting base plate comprises:
a first substrate base plate;
a plurality of switch elements provided on the first substrate base plate; and
a plurality of the light emitting devices according to any one of the above embodiments that are connected to the switch elements.

In an alternative implementation, the light emitting base plate further comprises:
a thin-film packaging layer provided on one side of the light emitting devices that is opposite to the first substrate base plate, wherein an orthographic projection of the thin-film packaging layer on the first substrate base plate covers the first substrate base plate.

In an alternative implementation, the light emitting base plate further comprises:
a color converting layer, provided on a light exiting side of the light emitting devices, for receiving an incident light ray, and emitting a light ray whose color is different from a color of the incident light ray, wherein the incident light ray is a light ray emitted by the light emitting devices.

In an alternative implementation, the incident light ray comprises a blue-color light ray and a first green-color light ray, the light emitting base plate comprises a plurality of pixels, each of the pixels comprises a red-color sub-pixel, a blue-color sub-pixel and at least one green-color sub-pixel, and the at least one green-color sub-pixel includes a first green-color sub-pixel and/or a second green-color sub-pixel; and
the color converting layer comprises at least one of:
   a first color converting pattern, located at the red-color sub-pixel, for emitting a red-color light ray when excited by the incident light ray;
   a second color converting pattern, located at the first green-color sub-pixel, for emitting a second green-color light ray when excited by the incident light ray;
   a first transmitting pattern, located at the second green-color sub-pixel, for transmitting the incident light ray; and
   a second transmitting pattern, located at the blue-color sub-pixel, for transmitting the incident light ray.

In an alternative implementation, a thickness of the second color converting pattern is less than a thickness of the first color converting pattern.

In an alternative implementation, the first color converting pattern is doped by a first scattering particle, and the second color converting pattern is doped by a second scattering particle; and
a doping proportion of the first scattering particle in the first color converting pattern is greater than or equal to a doping proportion of the second scattering particle in the second color converting pattern.

In an alternative implementation, an absolute value of a difference between a central wavelength of the first green-color light ray and a central wavelength of the second green-color light ray is less than or equal to 5 nanometers; and/or
an absolute value of a difference between a peak wavelength of the first green-color light ray and a peak wavelength of the second green-color light ray is less than or equal to 5 nanometers.

In an alternative implementation, the color converting layer comprises a color converting material, and the color converting material comprises at least one of a quantum dot, a rare-earth material, a fluorescent material and an organic dye.

In an alternative implementation, the light emitting base plate further comprises:
a color filtering layer provided on a light exiting side of the color converting layer, wherein the color filtering layer comprises:
   a first color filtering pattern, located at the red-color sub-pixel, for transmitting a red-color light ray entering the first color filtering pattern;
   a second color filtering pattern, located at the at least one green-color sub-pixel, for transmitting a green-color light ray entering the second color filtering pattern; and
   a third color filtering pattern, located at the blue-color sub-pixel, for transmitting a blue-color light ray entering the third color filtering pattern.

In an alternative implementation, the light emitting base plate further comprises:
a second substrate base plate provided on one side of the color filtering layer that is opposite to the color converting layer; and
a packing layer, provided between the thin-film packaging layer and the color converting layer, for adhesively bonding the thin-film packaging layer and the color converting layer;
wherein the thin-film packaging layer is located between the light emitting devices and the color converting layer.

The present disclosure provides a light emitting apparatus, wherein the light emitting apparatus comprises:
the light emitting base plate according to any one of the above embodiments;
a driving integrated circuit configured for providing a driving signal to the light emitting base plate; and
a power supply circuit configured for providing an electric power supply to the light emitting base plate.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work. It should be noted that the scales in the drawings are merely illustrative and do not indicate the actual scales.

FIG. 1 illustratively shows a schematic sectional structural diagram of the first type of light emitting device according to the present disclosure;

FIG. 2 illustratively shows a schematic sectional structural diagram of the second type of light emitting device according to the present disclosure;

FIG. 3 illustratively shows a schematic sectional structural diagram of the third type of light emitting device according to the present disclosure;

FIG. 4 illustratively shows a schematic sectional structural diagram of the fourth type of light emitting device according to the present disclosure;

FIG. 5 illustratively shows a schematic sectional structural diagram of the fifth type of light emitting device according to the present disclosure;

FIG. 6 illustratively shows a schematic sectional structural diagram of the sixth type of light emitting device according to the present disclosure;

FIG. 7 illustratively shows curve diagrams of the spectral characteristics of several light emitting devices;

FIG. 8 illustratively shows the result of luminous-efficiency tests at different sub-pixels of several light emitting devices;

FIG. 9 illustratively shows a schematic sectional structural diagram of the first type of light emitting base plate according to the present disclosure;

FIG. 10 illustratively shows a schematic sectional structural diagram of the second type of light emitting base plate according to the present disclosure;

FIG. 11 illustratively shows a schematic sectional structural diagram of the third type of light emitting base plate according to the present disclosure;

FIG. 12 illustratively shows a schematic sectional structural diagram of the fourth type of light emitting base plate according to the present disclosure;

FIG. 13 illustratively shows a schematic planar structural diagram of a light emitting base plate according to the present disclosure;

FIG. 14 illustratively shows an exemplary schematic sectional structural diagram of a first color converting pattern;

FIG. 15 illustratively shows an exemplary schematic sectional structural diagram of a second color converting pattern;

FIG. 16 illustratively shows an exemplary schematic sectional structural diagram of a first transmitting pattern; and

FIG. 17 illustratively shows an exemplary schematic sectional structural diagram of a second transmitting pattern.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

The present disclosure provides a light emitting device. Referring to FIGS. 1 to 6, FIGS. 1 to 6 illustratively show a schematic sectional structural diagram of a light emitting device according to the present disclosure. As shown in FIGS. 1 to 6, the light emitting device comprises: a first electrode 11; a second electrode 12 facing the first electrode 11; and at least one luminescent layer 13 provided in stack between the first electrode 11 and the second electrode 12.

The at least one luminescent layer 13 comprises: a first luminescent material for emitting a first light ray when driven by a current or voltage; and a second luminescent material for emitting a second light ray when driven by a current or voltage. The color of the first light ray and the color of the second light ray are different.

The first electrode 11 and the second electrode 12 are for providing a driving current or a driving voltage to the luminescent layer 13.

In the light emitting device according to the present disclosure, the luminescent layer 13 uses two different luminescent materials, i.e., the first luminescent material and the second luminescent material, so that the light emitting device, by the driving by the current or voltage, can emit two light rays of different colors, i.e., a mixed light ray of the first light ray and the second light ray.

When the light emitting device according to the present disclosure is used to irradiate the color converting material (for example, a quantum dot), because the light emitting device emits the mixed light ray of the first light ray and the second light ray, the first luminescent material and the second luminescent material may be regulated according to the luminous efficiencies of the luminescent materials and the brightness conversion rate of the light excitation on the color converting material by the emitted light rays of the luminescent materials, which can reach the purpose of increasing the brightness of the emitted light ray of the color converting material.

As compared with the solutions in which all of the luminescent layers 13 of the light emitting device use the same one type of luminescent material (for example, the first luminescent material or the second luminescent material), the light emitting device according to the embodiments of the present disclosure can increase the white-light efficiency of the color converting material, and reduce the power consumption of the device.

The luminous efficiency of a luminescent material refers to the ratio of the luminous flux of the light ray emitted by the luminescent material to the consumed electric power. The brightness conversion rate of the light excitation on a color converting material by the emitted light ray of a luminescent material refers to the ratio of the brightness of the light ray exiting the color converting material to the brightness of the emitted light ray of the luminescent material when the emitted light ray of the luminescent material irradiates the color converting material.

The light emitting device emits light by electrical driving, and the color converting material emits light by optical driving. In the combined device formed by the light emitting device and the color converting material, the color converting material emits light when excited by the emitted light ray of the light emitting device. In such a case, the white-light efficiency of the color converting material refers to the ratio of the brightness of the white-color light ray emitted by the color converting material (for example, comprising a red-color light ray, a blue-color light ray and a green-color light ray) to the electric-current density driving the light emitting device to emit light.

In some illustrative embodiments, the first light ray is a blue-color light ray, and the second light ray is a visible-light ray other than a blue-color light ray. For example, the second light ray may be a green-color light ray, a yellow-color light ray, a red-color light ray and so on.

Optionally, the wavelength of the first light ray is greater than or equal to 440 nanometers, and less than or equal to 490 nanometers. Optionally, the wavelength of the first light ray is greater than or equal to 450 nanometers, and less than or equal to 470 nanometers. For example, the wavelength of the first light ray is 455 nanometers, 460 nanometers, 465 nanometers and so on.

Optionally, the wavelength of the second light ray is greater than or equal to 500 nanometers, and less than or equal to 650 nanometers.

Optionally, the second light ray is a green-color light ray. As an example, the wavelength of the second light ray is greater than or equal to 520 nanometers, and less than or equal to 540 nanometers.

Optionally, the second light ray is a yellow-color light ray. As an example, the wavelength of the second light ray is greater than or equal to 580 nanometers, and less than or equal to 590 nanometers.

Optionally, the second light ray is a red-color light ray. As an example, the wavelength of the second light ray is greater than or equal to 620 nanometers, and less than or equal to 640 nanometers.

Optionally, both of the FWHMs (full width at half maxima) of the first light ray and the 15 second light ray are less than or equal to 40 nm. Optionally, both of the FWHMs of the first light ray and the second light ray are less than or equal to 20 nm, to increase the color purities of the first light ray and the second light ray.

In order to compare the performances of the light emitting devices, the inventor has tested the performances of three light emitting devices (including a light emitting device A, a light emitting device B and a light emitting device C). All of the light emitting device A, the light emitting device B and the light emitting device C are single-luminescent-layer light emitting devices. The light emitting devices A and B are comparative examples, and the light emitting device C is an experimental example. The luminescent layer of the light emitting device A comprises a luminescent material that can emit a green light, the luminescent layer of the light emitting device B comprises a luminescent material that can emit a blue light, and the luminescent layer 13 of the light emitting device C comprises a luminescent material that can emit a blue light and a luminescent material that can emit a green light. The color converting materials used in the test are quantum dots. The test result is as follows:

The light emitting device A emits an initial green light, with a luminous efficiency of 120cd/A. The brightness conversion rate of the light excitation on a green-light quantum dot (i.e., a quantum dot that can emit a green light) by the initial green light to emit a green light is 20%-25%, and the corresponding green-light luminous efficiency is 24cd/A-30cd/A. The brightness conversion rate when the initial green light directly passes through a light filtering layer to emit a green light is approximately 98%, and the corresponding green-light luminous efficiency is approximately 107cd/A. The brightness conversion rate of the light excitation on a red-light quantum dot (i.e., a quantum dot that can emit a red light) by the initial green light to emit a red light is 15%-25%, and the corresponding red-light luminous efficiency is 18cd/A-30cd/A.

The light emitting device B emits an initial blue light, with a luminous efficiency of 7.5cd/A. The brightness conversion rate of the light excitation on a green-light quantum dot by the initial blue light to emit a green light is 60%-150%, and the corresponding green-light luminous efficiency is 4.5cd/A-11.25cd/A. The brightness conversion rate of the light excitation on a red-light quantum dot by the initial blue light to emit a red light is 30%-60%, and the corresponding red-light luminous efficiency is 2.25cd/A-4.5cd/A. Therefore, the white-light efficiency (the sum of the blue-light luminous efficiency, the red-light luminous efficiency and the green-light luminous efficiency) of the light emitting device B is 14.25cd/A-23.25cd/A.

The light emitting device C emits an initial green light and an initial blue light, the luminous efficiency of the initial green light is greater than or equal to 40cd/A, and the luminous efficiency of the initial blue light is approximately 4cd/A. The green-light luminous efficiency after the initial green light has passed through a green-light quantum dot is 8cd/A-10cd/A, the green-light luminous efficiency after the initial green light has directly passed through a light filtering layer can reach 38cd/A, and the red-light luminous efficiency after the initial green light has passed through a red-light quantum dot is 6cd/A-10cd/A. The red-light luminous efficiency after the initial blue light has passed through a red-light quantum dot is 1.2cd/A-2.4cd/A, and the green-light luminous efficiency after the initial blue light has passed through a green-light quantum dot is 2.4cd/A-6cd/A.

It is obtained by calculation that, in the case that the initial green light passes through a green-light quantum dot, the white-light efficiency of the light emitting device C is 21.6cd/A-32.4cd/A, in the case that the initial green light directly passes through a light filtering layer, the white-light efficiency of the light emitting device C is 49.2cd/A-54.4cd/A. Accordingly, it can be seen that, as compared with the light emitting device B, the white-light efficiency of the light emitting device C has been highly increased.

In some illustrative embodiments, the first light ray is a blue-color light ray, and the second light ray is a green-color light ray. Correspondingly, the first luminescent material is a luminescent material that can emit a blue-color light ray. The second luminescent material is a luminescent material that can emit a green-color light ray.

In a particular implementation, the light emitting device may comprise one luminescent layer 13, may also comprise a plurality of luminescent layers 13 that are arranged in stack, as shown in FIGS. 1 to 6.

When the light emitting device comprises merely one luminescent layer 13, the first luminescent material and the second luminescent material are located in the same one luminescent layer 13.

When the light emitting device comprises a plurality of luminescent layers 13 that are arranged in stack, as shown in FIGS. 1 to 6, each of the plurality of luminescent layers 13 may comprise the first luminescent material, or the second luminescent material, or the first luminescent material and the second luminescent material, which is not limited in the present disclosure.

In some illustrative embodiments, as shown in FIGS. 1 to 6, the at least one luminescent layer 13 comprises a plurality of luminescent layers 13 that are arranged in stack.

The plurality of luminescent layers 13 include at least one first luminescent layer 131 and at least one second luminescent layer 132.

The first luminescent layer 131 comprises the first luminescent material. The second luminescent layer 132 comprises the second luminescent material, or the second luminescent layer 132 comprises the first luminescent material and the second luminescent material.

Optionally, the first electrode 11 is a reflection-type electrode, and the second electrode 12 is a transmission-type electrode or a semi-transmission-type electrode.

In a particular implementation, the first electrode 11 may employ a metal material such as magnesium and silver, and the second electrode 12 may employ a metal-oxide material such as indium tin oxide.

Optionally, the luminous efficiency of the first luminescent material is less than or equal to the luminous efficiency of the second luminescent material, and the first luminescent layer 131 is located on the side of the second luminescent layer 132 that is closer to the first electrode 11, as shown in FIGS. 1 to 6.

The luminous efficiency of the first luminescent material refers to the ratio of the luminous flux of the light ray emitted by the first luminescent material (i.e., the first light ray) to the consumed electric power. The luminous efficiency of the second luminescent material refers to the ratio of the luminous flux of the light ray emitted by the second luminescent material (i.e., the second light ray) to the consumed electric power.

Because the first electrode 11 is a reflection-type electrode, and the second electrode 12 is a transmission-type electrode or a semi-transmission-type electrode, the plurality of luminescent layers 13 are located within a resonant cavity formed by a reflecting film (i.e., a reflection-type electrode: the first electrode 11) and a transmitting film (i.e., a transmission-type electrode or semi-transmission-type electrode: the second electrode 12), and a microcavity structure is formed between the reflecting film and the transmitting film.

Because the luminous efficiency of the first luminescent layer 131 is less than the luminous efficiency of the second luminescent layer 132, by providing the first luminescent layer 131 at a position closer to the first electrode 11, in the microcavity structure, the first luminescent layer 131 of a lower luminous efficiency is closer to the reflecting film, which can reduce the influence by the first luminescent layer 131 on the overall luminous efficiency of the light emitting device.

Because the second luminescent layer 132 has a higher luminous efficiency, by providing the second luminescent layer 132 at a position further from the first electrode 11, in the microcavity structure, the second luminescent layer 132 of a higher luminous efficiency is further from the reflecting film, which facilitates to increase the overall luminous efficiency of the light emitting device.

Optionally, as shown in FIGS. 1 to 6, the at least one first luminescent layer 131 is located on the side of the at least one second luminescent layer 132 that is closer to the first electrode 11. In other words, all of the first luminescent layers 131 of the light emitting device are located on the side of all of the second luminescent layers 132 that is closer to the first electrode 11.

As an example, as shown in FIG. 1, the plurality of luminescent layers 13 include one first luminescent layer 131 and one second luminescent layer 132, and the first luminescent layer 131 is located on the side of the second luminescent layer 132 that is closer to the first electrode 11. In other words, the first electrode 11, the first luminescent layer 131, the second luminescent layer 132 and the second electrode 12 are arranged sequentially in stack.

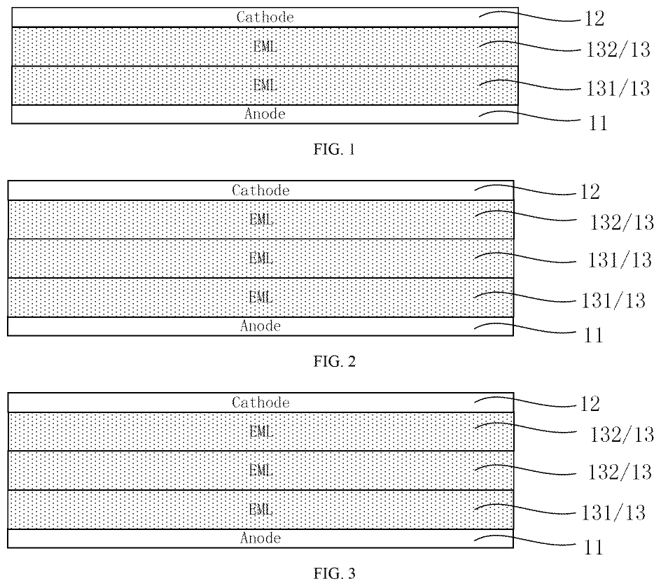

As an example, as shown in FIG. 2, the plurality of luminescent layers 13 include two first luminescent layers 131 and one second luminescent layer 132, and the two first luminescent layers 131 are located on the side of the second luminescent layer 132 that is closer to the first electrode 11. In other words, the first electrode 11, the two first luminescent layers 131, the second luminescent layer 132 and the second electrode 12 are arranged sequentially in stack.

As an example, as shown in FIG. 3, the plurality of luminescent layers 13 include one first luminescent layer 131 and two second luminescent layers 132, and the first luminescent layer 131 is located on the side of the two second luminescent layers 132 that is closer to the first electrode 11. In other words, the first electrode 11, the first luminescent layer 131, the two second luminescent layers 132 and the second electrode 12 are arranged sequentially in stack.

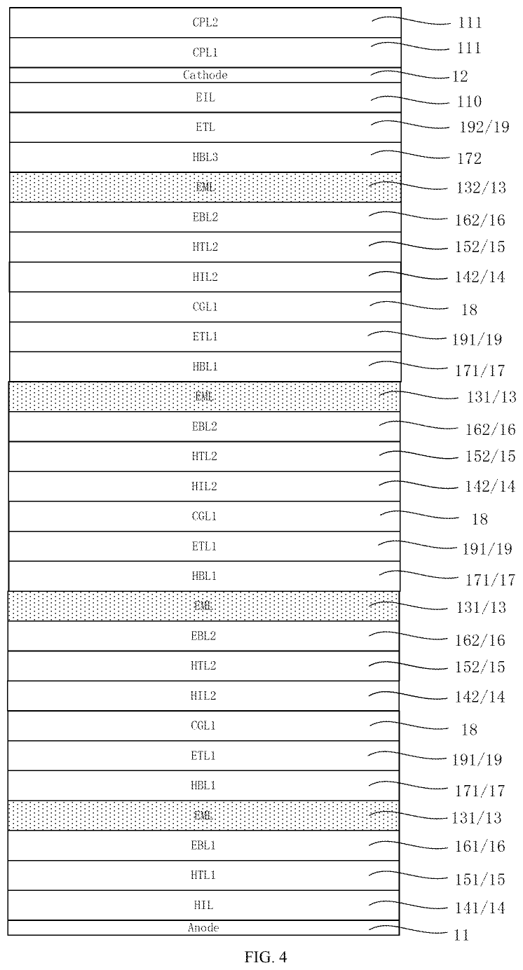

As an example, as shown in FIG. 4, the plurality of luminescent layers 13 include three first luminescent layers 131 and one second luminescent layer 132, and the three first luminescent layers 131 are located on the side of the second luminescent layer 132 that is closer to the first electrode 11. In other words, the first electrode 11, the three first luminescent layers 131, the second luminescent layer 132 and the second electrode 12 are arranged sequentially in stack.

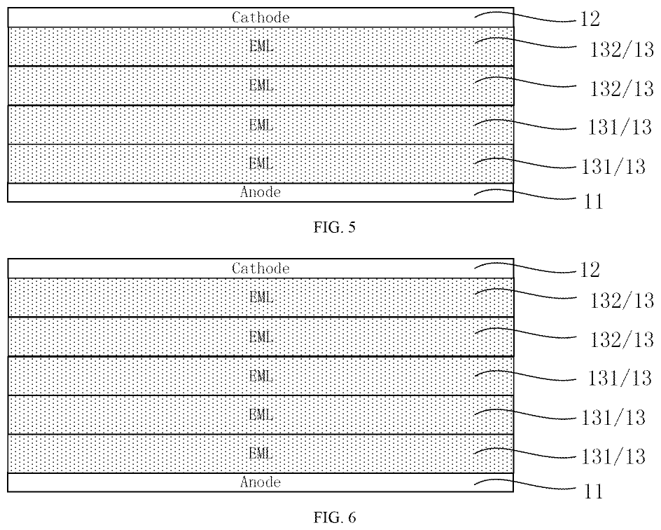

As an example, as shown in FIG. 5, the plurality of luminescent layers 13 include two first luminescent layers 131 and two second luminescent layers 132, and the two first luminescent layers 131 are located on the side of the two second luminescent layers 132 that is closer to the first electrode 11. In other words, the first electrode 11, the two first luminescent layers 131, the two second luminescent layers 132 and the second electrode 12 are arranged sequentially in stack.

As an example, as shown in FIG. 6, the plurality of luminescent layers 13 include three first luminescent layers 131 and two second luminescent layers 132, and the three first luminescent layers 131 are located on the side of the two second luminescent layers 132 that is closer to the first electrode 11. In other words, the first electrode 11, the three first luminescent layers 131, the two second luminescent layers 132 and the second electrode 12 are arranged sequentially in stack.

As an example, the plurality of luminescent layers 13 may also include four first luminescent layers 131 and one second luminescent layer 132, and the four first luminescent layers 131 are located on the side of the second luminescent layer 132 that is closer to the first electrode 11. In other words, the first electrode 11, the four first luminescent layers 131, the second luminescent layer 132 and the second electrode 12 are arranged sequentially in stack.

In a particular implementation, the stacking structure of the first luminescent layer 131 and the second luminescent layer 132 is not limited to the above-described types. For example, the first luminescent layers 131 and the second luminescent layers 132 may also be arranged alternately between the first electrode 11 and the second electrode 12, wherein the first luminescent layers 131 are located on the side of the second luminescent layers 132 that is closer to the first electrode 11, the first luminescent layers 131 may also be located on the side of the second luminescent layers 132 that is closer to the second electrode 1211, and so on. That is not limited in the present disclosure.

Optionally, as shown in FIG. 4, the light emitting device further comprises: one or more of functional film layers that are arranged in stack between the first electrode 11 and the second electrode 12 such as a hole injection layer 14, a hole transporting layer 15, an electron blocking layer 16, a hole blocking layer 17, an electric-charge generating layer 18, an electron transporting layer 19 and an electron injection layer 110.

One or more of the above-described functional film layers may be arranged in stack between the first electrode 11 and the at least one luminescent layer 13, may also be arranged in stack between two neighboring luminescent layers 13, and may also be arranged in stack between the at least one luminescent layer 13 and the second electrode 12, which may be particularly configured according to practical demands.

As an example, the electric-charge generating layer 18 may be provided between any two neighboring luminescent layers 13, and the electric-charge generating layer 18 can connect in series the at least one luminescent layer 13, to form a series-connected light emitting device.

In the series-connected light emitting device, the electric-charge generating layer 18 can inject charge carriers (for example, holes or electrons) into the neighboring luminescent layers 13. Regarding a certain luminescent layer 13, part of its charge carriers are supplied by the first electrode 11 and the second electrode 12, and the other part of its charge carriers are generated in the electric-charge generating layer 18. Therefore, the electric-charge generating layer 18 can increase the life of the light emitting device, and at the same time reduce the power consumption.

Optionally, the first electrode 11 is an anode, and the second electrode 12 is a cathode.

Optionally, as shown in FIG. 4, the light emitting device further comprises: a first hole injection layer 141, a first hole transporting layer 151 and a first electron blocking layer 161 that are arranged in stack between the first electrode 11 and the at least one luminescent layer 13, wherein the first hole injection layer 141 is closer to the first electrode 11.

Optionally, the light emitting device further comprises: a first hole blocking layer 171, a first electron transporting layer 191, an electric-charge generating layer 18, a second hole injection layer 142, a second hole transporting layer 152 and a second electron blocking layer 162 that are arranged in stack between two neighboring luminescent layers 13, wherein the first hole blocking layer 171 is closer to the first electrode 11.

Optionally, the light emitting device further comprises: a second hole blocking layer 172, a second electron transporting layer 192 and an electron injection layer 110 that are arranged in stack between the at least one luminescent layer 13 and the second electrode 12, wherein the electron injection layer 110 is closer to the second electrode 12.

Optionally, the light emitting device further comprises: at least one optical-extraction layer 111 provided on the side of the second electrode 12 that is opposite to the first electrode 11, wherein the at least one optical-extraction layer 111 is provided in stack.

As an example, the thicknesses of the sequentially stacked film layers are: the first electrode 11: 8 nanometers; the first hole injection layer 141: 10 nanometers; the first hole transporting layer 151: 115 nanometers; the first electron blocking layer 161: 10 nanometers; the first luminescent layer 131: 25 nanometers; the first hole blocking layer 171: 5 nanometers; the first electron transporting layer 191: 30 nanometers; the electric-charge generating layer 18: 15 nanometers; the second hole injection layer 142: 10 nanometers; the second hole transporting layer 152: 15 nanometers; the second electron blocking layer 162: 10 nanometers; the first luminescent layer 131: 25 nanometers; the first hole blocking layer 171: 5 nanometers; the first electron transporting layer 191: 25 nanometers; the electric-charge generating layer 18: 15 nanometers; the second hole injection layer 142: 10 nanometers; the second hole transporting layer 152: 15 nanometers; the second electron blocking layer 162: 10 nanometers; the first luminescent layer 131: 25 nanometers; the first hole blocking layer 171: 5 nanometers; the first electron transporting layer 191: 25 nanometers; the electric-charge generating layer 18: 30 nanometers; the second hole injection layer 142: 10 nanometers; the second hole transporting layer 152: 100 nanometers; the second electron blocking layer 162: 10 nanometers; the second luminescent layer 132: 30 nanometers; the second hole blocking layer 172: 5 nanometers; the second electron transporting layer 192: 25 nanometers; the electron injection layer 110: 1 nanometer; the second electrode 12: 12 nanometers; the optical-extraction layer 111: 80 nanometers; and the optical-extraction layer 111: 60 nanometers.

The light emitting device shown in FIG. 1 comprises two luminescent layers 13 that are arranged in stack, and is a double-tandem light emitting device. The light emitting devices shown in FIGS. 2 and 3 comprise three luminescent layers 13 that are arranged in stack, and are triple-tandem light emitting devices. The light emitting devices shown in FIGS. 4 and 5 comprise four luminescent layers 13 that are arranged in stack, and are quadruple-tandem light emitting devices. The light emitting device shown in FIG. 6 comprises five luminescent layers 13 that are arranged in stack, and is a quintuple-tandem light emitting device. As compared with a monolayer light emitting device, the multiple-tandem light emitting devices can effectively increase the luminous efficiency of the devices.

Optionally, both of the first luminescent material and the second luminescent material comprise at least one of an organic electroluminescent material and a quantum dot.

As an example, both of the first luminescent material and the second luminescent material are an organic electroluminescent material. Correspondingly, the light emitting device is an Organic Light Emitting Diode (OLED).

As an example, both of the first luminescent material and the second luminescent material are a quantum dot. Correspondingly, the light emitting device is a Quantum-Dot Light Emitting Diode (QLED).

Optionally, the first light ray is a blue-color light ray, the brightness of the first light ray emitted by the light emitting device is a first brightness, and the brightness of the total light ray emitted by the light emitting device is a second brightness, wherein the ratio of the first brightness to the second brightness is greater than or equal to 14%.

Only by setting the proportion of the brightness of the blue-color light ray in the total light ray to be greater than or equal to 14%, when the light emitting device is used to perform light excitation on the color converting material, it can be ensured that the ratio of the brightnesses of the red light, the green light and the blue light emitted by the color converting material can reach 3:6:1, and the demand on the white balance can be satisfied.

Optionally, the first light ray is a blue-color light ray, the spectral intensity of the first light ray emitted by the light emitting device is a first intensity, and the spectral intensity of the second light ray emitted by the light emitting device is a second intensity, wherein the first intensity is greater than or equal to the second intensity, and the second intensity is greater than 0.

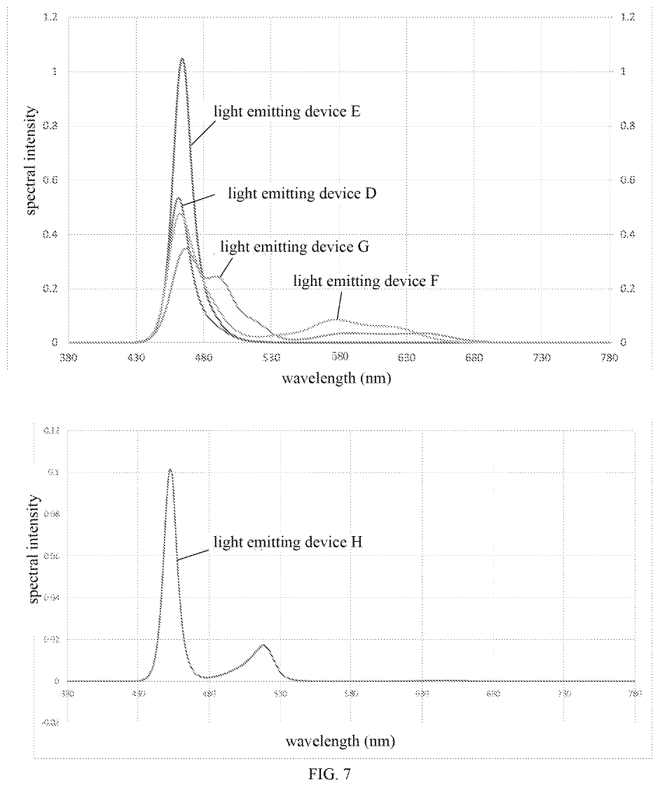

Referring to FIG. 7, FIG. 7 illustratively shows curve diagrams of the spectral characteristics of several light emitting devices. The light emitting device D is a single-tandem light emitting device, and comprises one first luminescent layer 131. The light emitting device E is a double-tandem light emitting device, and comprises two first luminescent layers 131 that are arranged in stack. The light emitting device F is the triple-tandem light emitting device shown in FIG. 2. The light emitting device G is a triple-tandem light emitting device, and comprises one first luminescent layer 131, one second luminescent layer 132 and one first luminescent layer 131 that are arranged sequentially in stack. The light emitting device H is the quadruple-tandem device shown in FIG. 4.

The first luminescent layers 131 of the above light emitting devices comprise the first luminescent material. The second luminescent layers 132 of the light emitting device F and the light emitting device G comprise the second luminescent material, and the second luminescent layer 132 of the light emitting device H comprises the first luminescent material and the second luminescent material. The first luminescent material can generate a blue-color light ray, and the second luminescent material can emit a green-color light ray.

Because the luminescent layers 13 of the light emitting device D and the light emitting device E comprise merely one luminescent material, i.e., the first luminescent material, the emitted light rays of the two light emitting devices have merely the first light ray, i.e., a blue-color light ray, the spectral intensity of the first light ray is greater than 0, and the spectral intensity of the second light ray is 0.

Because the luminescent layers 13 of the light emitting device F, the light emitting device G and the light emitting device H comprise the two luminescent materials, those light emitting devices can emit the mixed light ray of the first light ray and the second light ray, and the corresponding spectral curves have two peak values. Furthermore, as shown in FIG. 7, the spectral intensity of the first light ray, i.e., a blue-color light ray, is greater than the spectral intensity of the second light ray, i.e., a green-color light ray, and the spectral intensity of the second light ray is greater than 0.

As shown in FIG. 7, the two peak wavelengths of the emitted light ray of the light emitting device H are 453 nanometers and 523 nanometers.

In addition, by comparing the light emitting device F and the light emitting device G, it can be seen that the spectral intensities corresponding to the two peak values of the light emitting device F are higher, and the FWHMs are lower. That is because, in the light emitting device F, the two first luminescent layers 131 are located on the side of the second luminescent layer 132 that is closer to the first electrode 11, while in the light emitting device G, one of the first luminescent layers 131 is located on the side of the second luminescent layer 132 that is closer to the first electrode 11, and the other first luminescent layer 131 is located on the side of the second luminescent layer 132 that is closer to the second electrode 12.

It should be noted that, in the practical process, because of the limitation by the process conditions or other factors, the above-described same features may not be completely the same, and some errors might emerge. Therefore, the relation of sameness between the above-described features is merely required to substantially satisfy the above conditions, all of which fall within the protection scope of the present disclosure. For example, the above-described sameness may be sameness permitted within a permissible error range.

The present disclosure further provides a light emitting base plate. As shown in FIGS. 9 to 12, the light emitting base plate comprises: a first substrate base plate 50, a plurality of switch elements T provided on the first substrate base plate 50, and a plurality of the light emitting devices 51 according to any one of the above embodiments that are connected to the switch elements T.

A person skilled in the art can understand that the light emitting base plate has the advantages of the light emitting device described above.

In some embodiments, the light emitting base plate may be an illuminating base plate. In this case, the light emitting base plate serves as a light source, to realize the function of illumination. For example, the light emitting base plate may be a backlight module in a liquid-crystal displaying device, a lamp for internal illumination or external illumination, or various signal lamps.

In some other embodiments, the light emitting base plate may be a displaying base plate. In this case, the light emitting base plate has the function of displaying images (i.e., frames).

Optionally, as shown in FIGS. 9 to 12, the light emitting base plate may further comprise: a thin-film packaging layer 52 provided on the side of the plurality of light emitting devices 51 that is opposite to the first substrate base plate 50.

Optionally, the orthographic projection of the thin-film packaging layer 52 on the first substrate base plate 50 covers the first substrate base plate 50.

Optionally, as shown in FIGS. 9 to 12, the thin-film packaging layer 52 may comprise a first inorganic layer ENL1, an organic layer ENL2 and a second inorganic layer ENL3 that are arranged in stack.

Optionally, as shown in FIGS. 9 to 12, the light emitting base plate may further comprise: a color converting layer 53, provided on the light exiting side of the light emitting devices 51, for receiving an incident light ray, and emitting a light ray whose color is different from the color of the incident light ray, wherein the incident light ray is a light ray emitted by the light emitting devices 51.

When the light emitting base plate comprises the thin-film packaging layer 52 and the color converting layer 53, the color converting layer 53 is located on the side of the thin-film packaging layer 52 that is opposite to the first substrate base plate 50, as shown in FIGS. 9 to 12.

Optionally, as shown in FIG. 13, the light emitting base plate comprises an effective light emitting region DA and a border-frame region NDA located on at least one side of the effective light emitting region. The effective light emitting region DA may comprise a plurality of pixels.

Referring to FIGS. 9 to 12, FIGS. 9 to 12 show schematic sectional structural diagrams of one pixel within the effective light emitting region DA. As shown in FIGS. 9 to 12, each of the pixels comprises a red-color sub-pixel R, a blue-color sub-pixel B and at least one green-color sub-pixel G, and the at least one green-color sub-pixel G includes a first green-color sub-pixel G1 and/or a second green-color sub-pixel G2.

As shown in FIGS. 9 to 12, the plurality of light emitting devices 51 may comprise a first light emitting device LD1 located at the red-color sub-pixel R, a second light emitting device LD2 located at the green-color sub-pixel G and a third light emitting device LD3 located at the blue-color sub-pixel B. The sub-pixels and the light emitting devices 51 may correspond one to one.

Optionally, the incident light ray comprises a blue-color light ray and a first green-color light ray.

Optionally, as shown in FIGS. 9 to 12, the color converting layer 53 may comprise: a first color converting pattern CCP1, located at the red-color sub-pixel R, for emitting a red-color light ray when excited by the incident light ray.

The orthographic projection of the first color converting pattern CCP1 on the first substrate base plate 50 may cover the orthographic projection of the light emitting region (the opening region shown in the figures) of the first light emitting device LD1 on the first substrate base plate 50.

Optionally, as shown in FIGS. 9 to 12, the color converting layer 53 may further comprise: a second color converting pattern CCP2, located at the first green-color sub-pixel G1, for emitting a second green-color light ray when excited by the incident light ray.

The orthographic projection of the second color converting pattern CCP2 on the first substrate base plate 50 may cover the orthographic projection of the light emitting region (the opening region shown in the figures) of the second light emitting device LD2 on the first substrate base plate 50.

Optionally, as shown in FIGS. 9 to 12, the color converting layer 53 may further comprise: a first transmitting pattern TP1, located at the second green-color sub-pixel G2, for transmitting the incident light ray.

The orthographic projection of the first transmitting pattern TP1 on the first substrate base plate 50 may cover the orthographic projection of the light emitting region (the opening region shown in the figures) of the second light emitting device LD2 on the first substrate base plate 50.

Optionally, as shown in FIGS. 9 to 12, the color converting layer 53 may further comprise: a second transmitting pattern TP2, located at the blue-color sub-pixel B, for transmitting the incident light ray.

The orthographic projection of the second transmitting pattern TP2 on the first substrate base plate 50 may cover the orthographic projection of the light emitting region (the opening region shown in the figures) of the third light emitting device LD3 on the first substrate base plate 50.

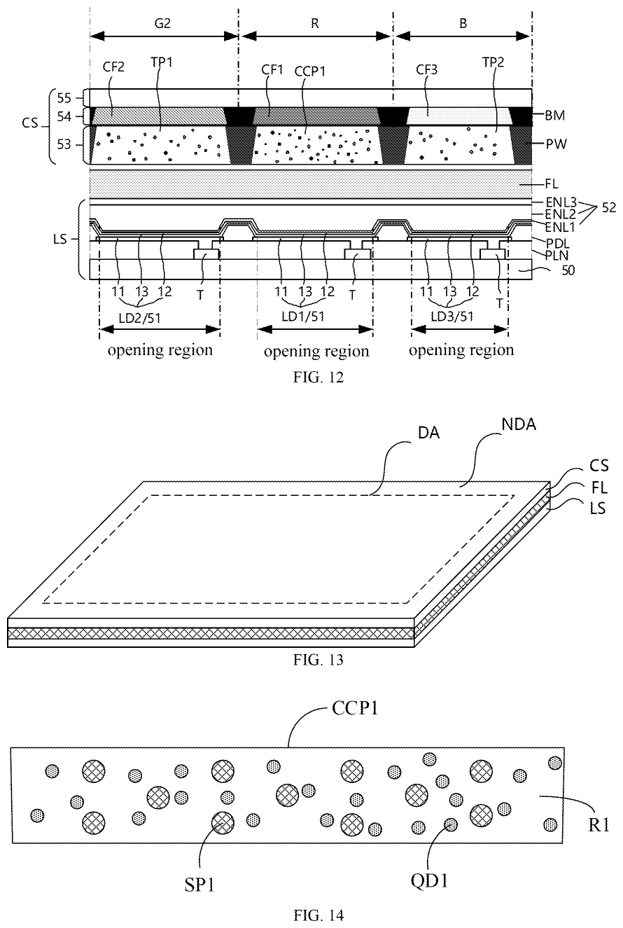

In the first illustrative example, as shown in FIG. 9 or 12, one pixel comprises one red-color sub-pixel R, one blue-color sub-pixel B and one green-color sub-pixel G, i.e., the second green-color sub-pixel G2.

Correspondingly, the color converting layer 53 comprises: the first color converting pattern CCP1 located at the red-color sub-pixel R, the first transmitting pattern TP1 located at the second green-color sub-pixel G2, and the second transmitting pattern TP2 located at the blue-color sub-pixel B.

Because the incident light ray contains a first green-color light ray, and when the first green-color light ray passes through the first transmitting pattern TP1 located within the green-color sub-pixel G to be transmitted, it can be realized that the green-color sub-pixel G emits a green-color light ray, the green-color sub-pixel G is not required to be provided with a color converting pattern therein, which can simplify the process, and save the process duration.

In the present example, the orthographic projection of the color converting layer 53 on the first substrate base plate 50 may also not intersect or overlap with the second green-color sub-pixel G2 and the blue-color sub-pixel B, which can further simplify the process, and save the process duration.

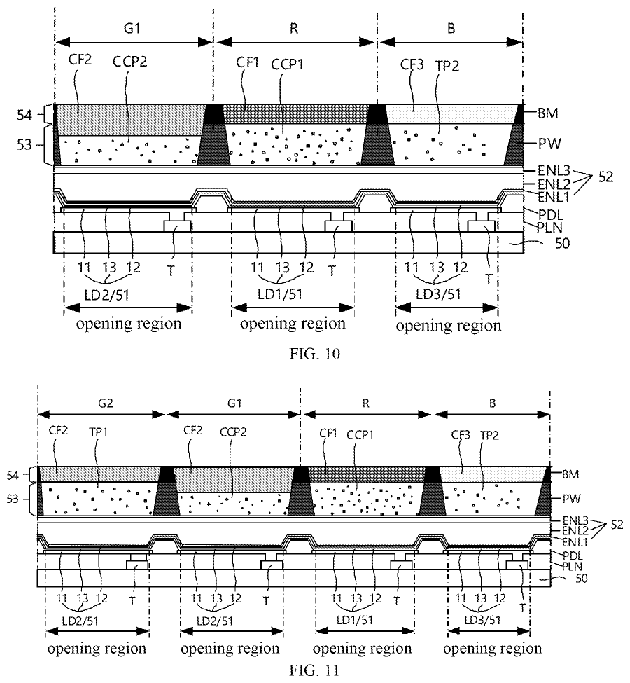

In the second illustrative example, as shown in FIG. 10, one pixel comprises one red-color sub-pixel R, one blue-color sub-pixel B and one green-color sub-pixel G, i.e., the first green-color sub-pixel G1.

Correspondingly, the color converting layer 53 comprises: the first color converting pattern CCP1 located at the red-color sub-pixel R, the second color converting pattern CCP2 located at the first green-color sub-pixel G1, and the second transmitting pattern TP2 located at the blue-color sub-pixel B.

In the present example, by providing the second color converting pattern CCP2 at the green-color sub-pixel G, the blue-color light ray in the incident light ray can be converted into the second green-color light ray, which can increase the brightness conversion rate of the incident light ray.

Optionally, as shown in FIG. 10, the thickness of the second color converting pattern CCP2 is less than the thickness of the first color converting pattern CCP1.

In order to prolong the propagation path of the blue-color light ray, to increase the brightness conversion rate, the second color converting pattern CCP2 may be doped by a scattering particle. However, the scattering particle reduces the transmittance of the first green-color light ray in the incident light ray. By providing the second color converting pattern CCP2 of a lower thickness, the scatterance of the first green-color light ray by the second color converting pattern CCP2 can be reduced, which increases the transmittance of the first green-color light ray.

For example, the thickness of the first color converting pattern CCP1 is greater than or equal to 10 micrometers, and the thickness of the second color converting pattern CCP2 is less than or equal to 10 micrometers.

Optionally, the first color converting pattern CCP1 is doped by a first scattering particle SP1, and the second color converting pattern CCP2 is doped by a second scattering particle SP2. The doping proportion of the first scattering particle SP1 in the first color converting pattern CCP1 is greater than or equal to the doping proportion of the second scattering particle SP2 in the second color converting pattern CCP2.

By reducing the doping proportion of the second scattering particle SP2 in the second color converting pattern CCP2, the scatterance of the first green-color light ray by the second color converting pattern CCP2 can be reduced, which increases the transmittance of the first green-color light ray.

In a particular implementation, the thickness of the second color converting pattern CCP2 and the doping proportion of the second scattering particle SP2 are adjusted, to enable the following inequation to be satisfied:

$$( {γ}_{BG} * x \% + ( 1 - x \% ) * {γ}_{G 1} > ( 1 - x \% ) * {γ}_{G 2} .$$

The light ray emitted by the light emitting devices 51 is the incident light ray, x % is the proportion of the blue-color light ray in the incident light ray, 1-x % is the proportion of the first green-color light ray in the incident light ray, YBG is the conversion rate when the blue-color light ray passes through the first green-color sub-pixel G1 and is converted into the second green-color light ray, γG1 is the transmittance when the first green-color light ray passes through the first green-color sub-pixel G1, and γG2 is the transmittance when the first green-color light ray passes through the second green-color sub-pixel G2.

In the inequation, the left side of the inequation represents the luminous efficiency of the first green-color sub-pixel G1, and the right side of the inequation represents the luminous efficiency of the second green-color sub-pixel G2. When the thickness of the second color converting pattern CCP2 and the doping proportion of the second scattering particle SP2 have been adjusted to enable the inequation to be satisfied, it can be realized that the luminous efficiency of the first green-color sub-pixel G1 is greater than the luminous efficiency of the second green-color sub-pixel G2.

Optionally, the absolute value of the difference between the central wavelength of the first green-color light ray and the central wavelength of the second green-color light ray is less than or equal to 5 nanometers. That can ensure that the central wavelength of the first green-color light ray and the central wavelength of the second green-color light ray substantially overlap, to increase the color purity of the green-color light ray.

Optionally, the absolute value of the difference between the peak wavelength of the first green-color light ray and the peak wavelength of the second green-color light ray is less than or equal to 5 nanometers. That can ensure that the peak wavelength of the first green-color light ray and the peak wavelength of the second green-color light ray substantially overlap, to increase the color purity of the green-color light ray.

In the third illustrative example, as shown in FIG. 11, one pixel comprises one red-color sub-pixel R, one blue-color sub-pixel B and two green-color sub-pixels G, i.e., the first green-color sub-pixel G1 and the second green-color sub-pixel G2.

Correspondingly, the color converting layer 53 comprises: the first color converting pattern CCP1 located at the red-color sub-pixel R, the second color converting pattern CCP2 located at the first green-color sub-pixel G1, the first transmitting pattern TP1 located at the second green-color sub-pixel G2, and the second transmitting pattern TP2 located at the blue-color sub-pixel B.

By providing the first green-color sub-pixel G1, the colour gamut can be increased, to modify the peak position of the emission of the green light of the green-color sub-pixel G, reduce the FWHM, and increase the color purity. In addition, by providing the second green-color sub-pixel G2, the brightness of the green-color sub-pixel G can be significantly increased.

As an example, as shown in FIGS. 9 to 12, the color converting layer 53 comprises a partitioning wall PW, and a plurality of color converting patterns located in a plurality of openings defined by the partitioning wall PW. The plurality of color converting patterns may include at least one of: the first color converting pattern CCP1, the second color converting pattern CCP2, the first transmitting pattern TP1 and the second transmitting pattern TP2.

The first color converting pattern CCP1 can emit light by converting or shifting the peak wavelength of an incident light to another specific peak wavelength. The first color converting pattern CCP1 can convert the emitted light L supplied by the first light emitting device LD1 into a red light having a peak wavelength within the range of approximately 610 nm to approximately 650 nm. As shown in FIG. 14, the first color converting pattern CCP1 may comprise a first base resin R1 and a first color converting material QD1 dispersed in the first base resin R1, and may comprise the first scattering particle SP1 dispersed in the first base resin R1.

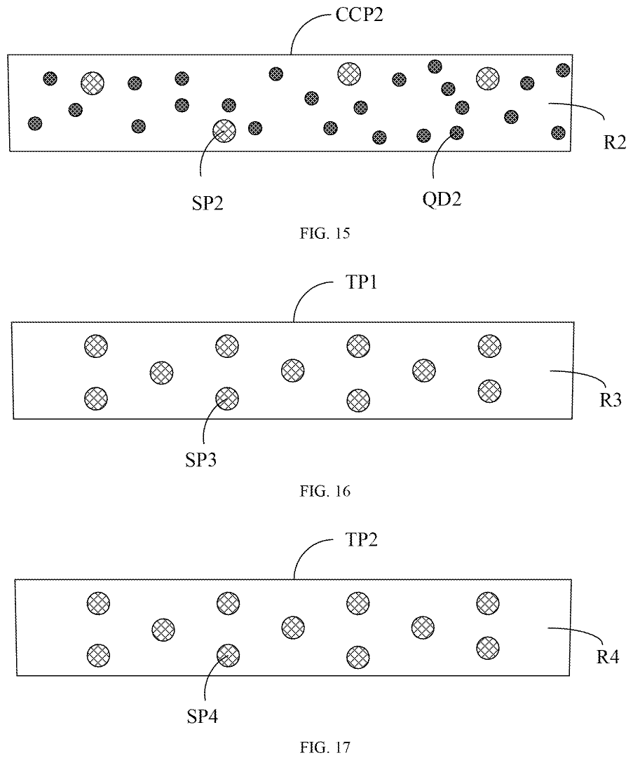

The second color converting pattern CCP2 can emit light by converting or shifting the peak wavelength of an incident light to another specific peak wavelength. The second color converting pattern CCP2 can convert the emitted light L supplied by the second light emitting device LD2 into a green light having a peak wavelength within the range of approximately 510 nm to approximately 550 nm. As shown in FIG. 15, the second color converting pattern CCP2 may comprise a second base resin R2 and a second color converting material QD2 dispersed in the second base resin R2, and may comprise the second scattering particle SP2 dispersed in the second base resin R2.

The first transmitting pattern TP1 can transmit the incident light, for example, with a transmissivity of over 90% to the peak wavelength of the incident light. The first transmitting pattern TP1 can transmit the emitted light L supplied by the second light emitting device LD2. As shown in FIG. 16, the first transmitting pattern TP1 may comprise a third base resin R3 and a third scattering particle SP3 dispersed in the third base resin R3. The third scattering particle SP3 can expand the visual-angle range of the incident light ray, and improve the visual-angle uniformity between the red-color sub-pixel R and the green-color sub-pixel G.

The second transmitting pattern TP2 can transmit the incident light, for example, with a transmissivity of over 90% to the peak wavelength of the incident light. The second transmitting pattern TP2 can transmit the emitted light L supplied by the third light emitting device LD3. As shown in FIG. 17, the second transmitting pattern TP2 may comprise a fourth base resin R4 and a fourth scattering particle SP4 dispersed in the fourth base resin R4. The fourth scattering particle SP4 can expand the visual-angle range of the incident light ray, and improve the visual-angle uniformity between the red-color sub-pixel R and the blue-color sub-pixel B.

The first color converting material QD1 and the second color converting material QD2 may comprise a semiconductor nanocrystal material, and can emit a light of a specific color when electrons transition from a conduction band to a valence band. The quantum dot may have any shape, as long as the shape is commonly used in the art. Furthermore, the quantum dot may particularly be a spherical, conical, multi-arm or cubic nanoparticle, or may be a nanotube, a nanowire, a nanofiber, a nanoparticle and so on.

In some embodiments, the quantum dot may have a core-shell structure. The core-shell structure comprises a core material and a shell material. The core-shell structure comprises a nanocrystal core and a shell surrounding the core. The shell of the quantum dot may serve as a protecting layer for preventing chemical modification of the core and maintaining the semiconductor characteristics, and/or as a charging layer for applying an electrophoresis characteristic to the quantum dot. The shell may have a monolayer structure or a multilayer structure. The interface between the core and the shell may have a concentration gradient by which the concentration of the elements in the shell decreases toward the center of the core. The core of the quantum dot may be selected from the group consisting of a group-II-VI compound, a group-III-V compound, a group-IV-VI compound, a group-IV element, a group-IV compound and a combination thereof. The shell of the quantum dot may comprise an oxide of a metal or non-metal material, a semiconductor compound, or a combination thereof. Between the core material and the shell material a transition material may be added, to realize the gradual transition of the crystal lattice, to effectively reduce the internal pressure caused by the lattice defect of the quantum dot, thereby further improving the luminous efficiency and the stability of the quantum dot.

In some embodiments, the group-II-VI compound may be selected from the group consisting of: CdSe, CdTe, ZnS, ZnSe, ZnTe, ZnO, HgS, HgSe, HgTe, MgSe, MgS, and a binary compound selected from the group consisting of the mixtures thereof; AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a ternary compound selected from the group consisting of the mixtures thereof; and HgZnTeS, CdZnSeS, CdZnSeTe, CdZnSTe, CdHgSeS, CdHgSeTe, CdHgSTe, HgZnSeS, HgZnSeTe, HgZnSTe, and a quaternary compound selected from the group consisting of the mixtures thereof.

In some embodiments, the group-III-V compound may be selected from the group consisting of: GaN, GaP, GaAs, GaSb, AlN, AlP, AlAs, AlSb, InN, InP, InAs, InSb, and a binary compound selected from the group consisting of the mixtures thereof; GaNP, GaNAs, GaNSb, GaPAs, GaPSb, AlNP, AlNAs, AlNSb, AlPAs, AlPSb, InGaP, InNAs, InNP, InNAs, InNSb, InPAs, InPSb, and a ternary compound selected from the group consisting of the mixtures thereof; and GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a quaternary compound selected from the group consisting of the mixtures thereof.

In some embodiments, the group-III-V compound may be selected from the group consisting of: GaN, GaP, GaAs, GaSb, AlN, AlP, AlAs, AlSb, InN, InP, InAs, InSb, and a binary compound selected from the group consisting of the mixtures thereof; GaNP, GaNAs, GaNSb, GaPAs, GaPSb, AlNP, AlNAs, AlNSb, AlPAs, AlPSb, InGaP, InNAs, InNP, InNAs, InNSb, InPAs, InPSb, and a ternary compound selected from the group consisting of the mixtures thereof; and GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a quaternary compound selected from the group consisting of the mixtures thereof.

In some embodiments, the transition material may be a ternary alloy material. By using the ternary alloy material to control the optical property of the quantum dot, quantum dots having the equal volume but unequal luminescence frequencies can be formed, to increase the colour-gamut coverage of the displaying device.

In some embodiments, the core material of the quantum dot comprises CdSe and/or InP, and the shell material comprises ZnS. Taking the case as an example in which the core material comprises InP, the surface defect of the InP quantum dot forms a surface trap state, and by coating the surface of the InP quantum dot with ZnS, the core-shell structure with InP as the core material and ZnS as the shell material is formed, which can reduce the surface defect of the quantum dot, and optimize the luminous efficiency and the stability of the quantum dot. The above is merely an example in which the core material comprises InP, and in the case that the core material comprises CdSe, or that the core material comprises CdSe and InP, the above rule is also satisfied.

In some embodiments, the quantum dot QD does not comprise cadmium (Cd). For example, the core material of QD is InP, and the shell material is the stacking of ZnSe/ZnS. As another example, the core material of QD is ZnTeSe, and the shell material is ZnSe/ZnS.

The quantum dot may have a size less than 45 nanometers (nm), for example, 40 nm, 30 nm, 20 nm or lower. In some embodiments, the size of the quantum dot is 4 nm-20 nm. As an example, it may be 4 nm, 5 nm, 7 nm, 10 nm, 13 nm, 17 nm or 20 nm. The quantum dot may regulate the color of the emitted light according to its size, and therefore the quantum dot may emit lights of various colors, for example, a blue light, a red light and a green light. The size of the red-color quantum dot and the size of the green-color quantum dot may be unequal.

The first color converting material QD1 and the second color converting material QD2 are not limited to the above-described quantum-dot materials, and the first color converting material QD1 and the second color converting material QD2 may also be one or more of color converting materials such as a quantum dot, a rare-earth material, a fluorescent material and an organic dye.

Quantum-dot materials, as a novel luminescent material, have the advantages such as a concentrated luminescence spectrum, a high colour gamut and a high color purity, and the emitted-light color can be simply regulated by using the size, the structure or the composition of the quantum-dot materials. In practical applications, a quantum-dot ink sequentially undergoes solution processing, spin coating or ink jetting, and subsequently is further solidified for film formation, to form a quantum-dot film layer, which can be used as the luminescent material for solid-state illumination and flat-plate displaying.

When the light emitting devices are an OLEDs and the color converting layer 53 uses a quantum-dot material, that can realize the combination between the pixel-grade controlling of the OLED and the characteristic of color augmentation of the quantum dot, to obtain a better display characteristic, and, at the same time, can reduce the power consumption, to prolong the service life of the light emitting base plate. In addition, in the fabrication of a plurality of light emitting devices 51, the luminescent layers 13 located at different sub-pixels may be formed as a whole face; for example, an open-type mask may be used, to synchronously form the luminescent layers 13 located at the different sub-pixels, which can simplify the fabricating process.

Optionally, as shown in FIGS. 9 to 12, each of the light emitting devices further comprises: a color filtering layer 54 provided on the light exiting side of the color converting layer 53.

Optionally, as shown in FIGS. 9 to 12, the color filtering layer 54 comprises: a first color filtering pattern CF1, located at the red-color sub-pixel R, for transmitting a red-color light ray entering the first color filtering pattern CF1.

Optionally, as shown in FIGS. 9 to 12, the color filtering layer 54 comprises: a second color filtering pattern CF2, located at the green-color sub-pixel G, for transmitting a green-color light ray entering the second color filtering pattern CF2.

Optionally, as shown in FIGS. 9 to 12, the color filtering layer 54 comprises: a third color filtering pattern CF3, located at the blue-color sub-pixel B, for transmitting a blue-color light ray entering the third color filtering pattern CF3.

In a particular implementation, referring to FIGS. 9 to 11, the plurality of switch elements T, a planarization layer PLN, the first electrode 11, a pixel defining layer PDL, the at least one luminescent layer 13, the second electrode 12, the thin-film packaging layer 52, the color converting layer 53 and the color filtering layer 54 may be sequentially formed on the first substrate base plate 50, to obtain the light emitting base plates shown in FIGS. 9 to 11.

Optionally, as shown in FIG. 12, each of the light emitting devices further comprises: a second substrate base plate 55 provided on the side of the color filtering layer 54 that is opposite to the color converting layer 53; and a packing layer FL, provided between the thin-film packaging layer 52 and the color converting layer 53, for adhesively bonding the thin-film packaging layer 52 and the color converting layer 53.

The thin-film packaging layer 52 is located between the plurality of light emitting devices 51 and the color converting layer 53.

In a particular implementation, the process may comprise forming sequentially the plurality of switch elements T, the planarization layer PLN, the first electrode 11, the pixel defining layer PDL, the at least one luminescent layer 13, the second electrode 12 and the thin-film packaging layer 52 on the first substrate base plate 50, to obtain the base plate LS of the light emitting base plate shown in FIG. 12; forming sequentially the color filtering layer 54 and the color converting layer 53 on the second substrate base plate 55, to obtain the base plate CS of the light emitting base plate shown in FIG. 12; and subsequently, adhesively bonding the base plate LS and the base plate CS together by using the packing layer FL, wherein the packing layer FL is located between the thin-film packaging layer 52 and the color converting layer 53, to obtain the light emitting base plate shown in FIG. 12.

In order to reach the white balance, it is required to satisfy that the red-light brightness: the green-light brightness: the blue-light brightness=3:6:1.

In some illustrative embodiments, the luminous efficiency of the blue-color light ray emitted by the light emitting devices is CEB, and the luminous efficiency of the first green-color light ray emitted by the light emitting devices is CEG.

The conversion rate when the blue-color light ray passes through the red-color sub-pixel R and is converted into the red-color light ray is γBR, and the conversion rate when the first green-color light ray passes through the red-color sub-pixel R and is converted into the red-color light ray is γ_{GR}. The conversion rate when the blue-color light ray passes through the first green-color sub-pixel G1 and is converted into the second green-color light ray is yBG, and the transmittance when the first green-color light ray passes through the first green-color sub-pixel G1 is γ_{G1}. The transmittance when the first green-color light ray passes through the second green-color sub-pixel G2 is γ_{G2}. The transmittance when the blue-color light ray passes through the blue-color sub-pixel B is γ_{B}.

According to the above parameters, it can be calculated that the luminous efficiency of the red-color sub-pixel R is: P_{R}=CE_{G}*γ_{GR}+CE_{B}*γ_{BR}; the luminous efficiency of the first green-color sub-pixel G1 is: P_{G1}=CE_{G}*γ_{G1}+CE_{B}*γ_{BG}; the luminous efficiency of the second green-color sub-pixel G2 is: P_{G2}=CE_{G}*γ_{G2}; and the luminous efficiency of the blue-color sub-pixel B is: P_{B}=CE_{B}*γ_{B}.

The total luminous efficiency of the green-color sub-pixel G is: P_{G}=a*P_{G1}+b*P_{G2}=a*(CE_{G}*γ_{G1}+CE_{B}*γ_{BG})+b*(CE_{G}*γ_{G2}). When the pixel comprises the first green-color sub-pixel G1, a=1, or else a=0. When the pixel comprises the second green-color sub-pixel G2, b=1, or else b=0.

In order to enable the light emitting base plate according to the present disclosure to reach the white balance, the above parameters may satisfy the following relation: P_{R}:P_{G}:P_{B}=(3/Ar):(6/Ag):(1/Ab), wherein Ar is the aperture ratio of the red-color sub-pixel R, Ag is the aperture ratio of the green-color sub-pixel G, and Ab is the aperture ratio of the blue-color sub-pixel B.

According to P_{G}:P_{B}=(6/Ag):(1/Ab), the luminous efficiency CE_{G} of the first green-color light ray emitted by the light emitting devices and the luminous efficiency CE_{B} of the blue-color light ray emitted by the light emitting devices are required to satisfy the following relations:

When the pixel comprises the red-color sub-pixel R, the blue-color sub-pixel B and the first green-color sub-pixel G1, as shown in FIG. 10, the relation required to be satisfied to reach the white balance is: P_{G1}:P_{B}=(CE_{G}*γ_{G1}+CE_{B}*γ_{BG}):CE_{B}*γ_{B}=(6/Ag):(1/Ab).

When the pixel comprises the red-color sub-pixel R, the blue-color sub-pixel B and the second green-color sub-pixel G2, as shown in FIG. 9 or 12, the relation required to be satisfied to reach the white balance is: P_{G2}:P_{B}=CE_{G}*γ_{G2}:CE_{B}*γ_{B}=(6/Ag):(1/Ab).

When the pixel comprises the red-color sub-pixel R, the blue-color sub-pixel B, the first green-color sub-pixel G1 and the second green-color sub-pixel G2, as shown in FIG. 11, the relation required to be satisfied to reach the white balance is:

$${P}_{G} : {P}_{B} = ( {CE}_{G} * {γ}_{G 1} + {CE}_{B} * {γ}_{BG} + {CE}_{G} * {γ}_{G 2} ) : {CE}_{B} * {γ}_{B} = ( 6 / Ag ) : ( 1 / Ab ) .$$

In some illustrative embodiments, the light ray emitted by the light emitting devices 51 is the incident light ray, the brightness of the incident light ray is L, x % is the proportion of the blue-color light ray in the incident light ray, 1-x % is the proportion of the first green-color light ray in the incident light ray, γ_{BG} is the conversion rate when the blue-color light ray passes through the first green-color sub-pixel G1 and is converted into the second green-color light ray, γ_{G1} is the transmittance when the first green-color light ray passes through the first green-color sub-pixel G1, γ_{G2} is the transmittance when the first green-color light ray passes through the second green-color sub-pixel G2, and γ_{G2} may be approximately equal to the transmittance of the second color filtering pattern CF2.

When the pixel comprises the red-color sub-pixel R, the blue-color sub-pixel B and the first green-color sub-pixel G1, as shown in FIG. 10, the brightness of the first green-color sub-pixel G1 is: x %*L*γ_{BG}+(1-x %)*L*γ_{G1}.

When the pixel comprises the red-color sub-pixel R, the blue-color sub-pixel B and the second green-color sub-pixel G2, as shown in FIG. 9 or 12, the brightness of the second green-color sub-pixel G2 is: (1-x %)*L*γ_{G2}.

When the pixel comprises the red-color sub-pixel R, the blue-color sub-pixel B, the first green-color sub-pixel G1 and the second green-color sub-pixel G2, as shown in FIG. 11, The brightness of the green-color sub-pixel G is the sum of the brightness of the first green-color sub-pixel G1 and the brightness of the second green-color sub-pixel G2, i.e.:

$$x \% * L * {γ}_{BG} + ( 1 - x \% ) * L * {γ}_{G 1} + ( 1 - x \% ) * L * {γ}_{G 2} .$$

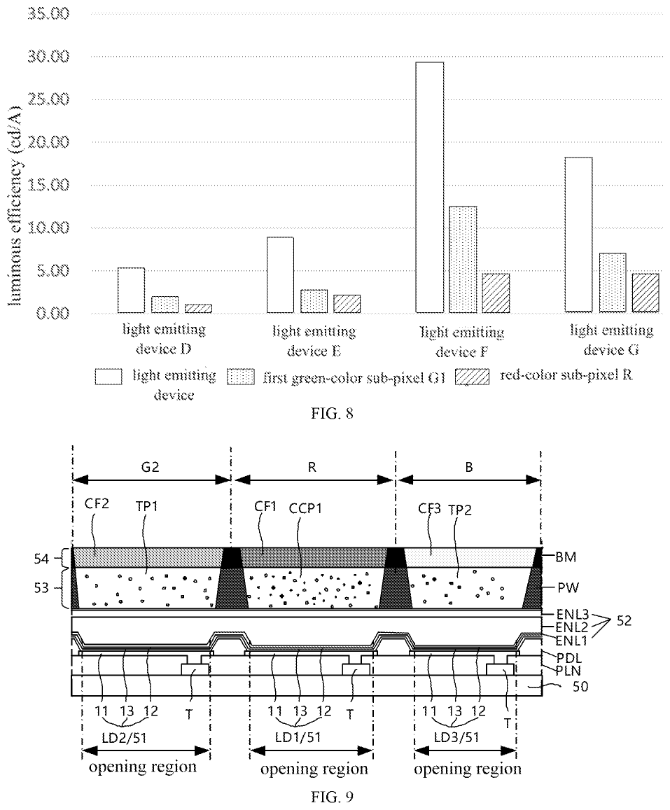

FIG. 8 illustratively shows the result of luminous-efficiency tests at different sub-pixels of several light emitting devices. In FIG. 8, the white-color-filled histograms are the self luminous efficiencies of the light emitting devices, the dot-filled histograms are the luminous efficiencies when the light rays emitted by the light emitting devices pass through the first green-color sub-pixel G1, and the line-filled histograms are the luminous efficiencies when the light rays emitted by the light emitting devices pass through the red-color sub-pixel R.

As shown in FIG. 8, because the luminescent layers 13 of the light emitting device D and the light emitting device E comprise merely one luminescent material, i.e., the first luminescent material, both of the self luminous efficiencies and the luminous efficiencies when the emitted light rays pass through the first green-color sub-pixel G1 or the red-color sub-pixel R of the light emitting devices are less than those of the light emitting device F and the light emitting device G.

In addition, by comparing the light emitting device F and the light emitting device G, both of the self luminous efficiency and the luminous efficiency when the emitted light ray passes through the first green-color sub-pixel G1 or the red-color sub-pixel R of the light emitting device F are superior to those of the light emitting device G.

The present disclosure further provides a light emitting apparatus, wherein the light emitting apparatus comprises: the light emitting base plate according to any one of the above embodiments; a driving integrated circuit configured for providing a driving signal to the light emitting base plate; and a power supply circuit configured for providing an electric power supply to the light emitting base plate.

A person skilled in the art can understand that the light emitting apparatus has the advantages of the light emitting base plate described above.

The light emitting apparatus may be a display or a product comprising a display. The display may be a Flat Panel Display (FPD), a microdisplay and so on. If classified based on whether the user can see the scene at the back face of the display, the display may be a transparent display or a non-transparent display. If classified based on whether the display can be bent or curled, the display may be a flexible display or a common display (which may be referred to as a rigid display). As an example, the product comprising a display may include: a computer, a television set, a billboard, a laser printer having the function of displaying, a telephone, a mobile phone, an electronic paper, a Personal Digital Assistant (PDA), a laptop computer, a digital camera, a tablet personal computer, a notebook computer, a navigator, a portable camcorder, a viewfinder, a vehicle, a large-area wall, a theater screen, a stadium scutcheon and so on.

The embodiments of the description are described in the mode of progression, each of the embodiments emphatically describes the differences from the other embodiments, and the same or similar parts of the embodiments may refer to each other.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

The light emitting device, the light emitting base plate and the light emitting apparatus according to the present disclosure have been described in detail above. The principle and the embodiments of the present disclosure are described herein with reference to the particular examples, and the description of the above embodiments is merely intended to facilitate to understand the method according to the present disclosure and its core concept. Moreover, for a person skilled in the art, according to the concept of the present disclosure, the particular embodiments and the range of application may be varied. In conclusion, the contents of the description should not be understood as limiting the present disclosure.

A person skilled in the art, after considering the description and implementing the invention disclosed herein, will readily envisage other embodiments of the present disclosure. The present disclosure aims at encompassing any variations, uses or adaptative alternations of the present disclosure, wherein those variations, uses or adaptative alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

It should be understood that the present disclosure is not limited to the accurate structure that has been described above and shown in the drawings, and may have various modifications and variations without departing from its scope. The scope of the present disclosure is merely limited by the appended claims.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A light emitting device, wherein the light emitting device comprises:
a first electrode;
a second electrode facing the first electrode; and
at least one luminescent layer provided in stack between the first electrode and the second electrode, wherein the at least one luminescent layer comprises:
a first luminescent material for emitting a first light ray when driven by a current or voltage; and
a second luminescent material for emitting a second light ray when driven by a current or voltage;
wherein a color of the first light ray and a color of the second light ray are different.

2. The light emitting device according to claim 1, wherein a wavelength of the first light ray is greater than or equal to 440 nanometers, and less than or equal to 490 nanometers.

3. The light emitting device according to claim 2, wherein a wavelength of the second light ray is greater than or equal to 500 nanometers, and less than or equal to 650 nanometers.

4. The light emitting device according to claim 1, wherein the at least one luminescent layer includes at least one first luminescent layer and at least one second luminescent layer;
the first luminescent layer comprises the first luminescent material; and
the second luminescent layer comprises the second luminescent material, or the second luminescent layer comprises the first luminescent material and the second luminescent material.

5. The light emitting device according to claim 4, wherein the first electrode is a reflection-type electrode, and the second electrode is a transmission-type electrode or a semi-transmission-type electrode; and
a luminous efficiency of the first luminescent material is less than or equal to a luminous efficiency of the second luminescent material, and the first luminescent layer is located on one side of the second luminescent layer that is closer to the first electrode.

6. The light emitting device according to claim 5, wherein the at least one first luminescent layer is located on one side of the at least one second luminescent layer that is closer to the first electrode.

7. The light emitting device according to claim 1, wherein the first electrode is an anode, the second electrode is a cathode, and the light emitting device further comprises at least one of:
a first hole injection layer, a first hole transporting layer and a first electron blocking layer that are arranged in stack between the first electrode and the at least one luminescent layer, wherein the first hole injection layer is closer to the first electrode;
a first hole blocking layer, a first electron transporting layer, an electric-charge generating layer, a second hole injection layer, a second hole transporting layer and a second electron blocking layer that are arranged in stack between two neighboring instances of the luminescent layer, wherein the first hole blocking layer is closer to the first electrode;
a second hole blocking layer, a second electron transporting layer and an electron injection layer that are arranged in stack between the at least one luminescent layer and the second electrode, wherein the electron injection layer is closer to the second electrode; and
an optical-extraction layer provided on one side of the second electrode that is opposite to the first electrode.

8. The light emitting device according to claim 1, wherein both of the first luminescent material and the second luminescent material comprise at least one of an organic electroluminescent material and a quantum dot.

9. The light emitting device according to claim 1, wherein the first light ray is a blue-color light ray;
a spectral intensity of the first light ray emitted by the light emitting device is a first intensity, and a spectral intensity of the second light ray emitted by the light emitting device is a second intensity, wherein the first intensity is greater than or equal to the second intensity, and the second intensity is greater than 0; and/or
a brightness of the first light ray emitted by the light emitting device is a first brightness, and a brightness of a total light ray emitted by the light emitting device is a second brightness, wherein a ratio of the first brightness to the second brightness is greater than or equal to 14%.

10. A light emitting base plate, wherein the light emitting base plate comprises:
a first substrate base plate;
a plurality of switch elements provided on the first substrate base plate; and
a plurality of the light emitting devices according to amclaim 1 that are connected to the switch elements.

11. The light emitting base plate according to claim 10, wherein the light emitting base plate further comprises:
a thin-film packaging layer provided on one side of the light emitting devices that is opposite to the first substrate base plate, wherein an orthographic projection of the thin-film packaging layer on the first substrate base plate covers the first substrate base plate.

12. The light emitting base plate according to claim 11, wherein the light emitting base plate further comprises:
a color converting layer, provided on a light exiting side of the light emitting devices, for receiving an incident light ray, and emitting a light ray whose color is different from a color of the incident light ray, wherein the incident light ray is a light ray emitted by the light emitting devices.

13. The light emitting base plate according to claim 12, wherein the incident light ray comprises a blue-color light ray and a first green-color light ray, the light emitting base plate comprises a plurality of pixels, each of the pixels comprises a red-color sub-pixel, a blue-color sub-pixel and at least one green-color sub-pixel, and the at least one green-color sub-pixel includes a first green-color sub-pixel and/or a second green-color sub-pixel; and
the color converting layer comprises at least one of:
a first color converting pattern, located at the red-color sub-pixel, for emitting a red-color light ray when excited by the incident light ray;
a second color converting pattern, located at the first green-color sub-pixel, for emitting a second green-color light ray when excited by the incident light ray;
a first transmitting pattern, located at the second green-color sub-pixel, for transmitting the incident light ray; and
a second transmitting pattern, located at the blue-color sub-pixel, for transmitting the incident light ray.

14. The light emitting base plate according to claim 13, wherein a thickness of the second color converting pattern is less than a thickness of the first color converting pattern.

15. The light emitting base plate according to claim 13, wherein the first color converting pattern is doped by a first scattering particle, and the second color converting pattern is doped by a second scattering particle; and
a doping proportion of the first scattering particle in the first color converting pattern is greater than or equal to a doping proportion of the second scattering particle in the second color converting pattern.

16. The light emitting base plate according to claim 13, wherein an absolute value of a difference between a central wavelength of the first green-color light ray and a central wavelength of the second green-color light ray is less than or equal to 5 nanometers; and/or
an absolute value of a difference between a peak wavelength of the first green-color light ray and a peak wavelength of the second green-color light ray is less than or equal to 5 nanometers.

17. The light emitting base plate according to claim 12, wherein the color converting layer comprises a color converting material, and the color converting material comprises at least one of a quantum dot, a rare-earth material, a fluorescent material and an organic dye.

18. The light emitting base plate according to claim 13, wherein the light emitting base plate further comprises:
a color filtering layer provided on a light exiting side of the color converting layer, wherein the color filtering layer comprises:
a first color filtering pattern, located at the red-color sub-pixel, for transmitting a red-color light ray entering the first color filtering pattern;
a second color filtering pattern, located at the at least one green-color sub-pixel, for transmitting a green-color light ray entering the second color filtering pattern; and
a third color filtering pattern, located at the blue-color sub-pixel, for transmitting a blue-color light ray entering the third color filtering pattern.

19. The light emitting base plate according to claim 18, wherein the light emitting base plate further comprises:
a second substrate base plate provided on one side of the color filtering layer that is opposite to the color converting layer; and
a packing layer, provided between the thin-film packaging layer and the color converting layer, for adhesively bonding the thin-film packaging layer and the color converting layer;
wherein the thin-film packaging layer is located between the light emitting devices and the color converting layer.

20. A light emitting apparatus, wherein the light emitting apparatus comprises:
the light emitting base plate according to claim 10;
a driving integrated circuit configured for providing a driving signal to the light emitting base plate; and
a power supply circuit configured for providing an electric power supply to the light emitting base plate.
